(19) United States
(12) Patent Application Publication
(10) Pub. No.: US 2012/0167954 A1
(43) Pub. Date: Jul. 5, 2012

(54) MONOLITHIC MODULE ASSEMBLY USING BACK CONTACT SOLAR CELLS AND METAL RIBBON

(75) Inventors: David H. Meakin, Albuquerque, NM (US); Fares Bagh, Austin, TX (US)

(73) Assignee: Applied Materials, Inc., Santa Clara, CA (US)

(21) Appl. No.: 13/419,176

(22) Filed: Mar. 13, 2012

Related U.S. Application Data
(63) Continuation of application No. 12/842,022, filed on Jul. 22, 2010.
(60) Provisional application No. 61/227,487, filed on Jul. 22, 2009.

(51) Int. Cl. H01L 31/05

(52) U.S. Cl. 136/249

(57) ABSTRACT

Embodiments of the invention contemplate the formation of a solar cell module comprising an array of interconnected solar cells that are formed using an automated processing sequence that is used to form a novel solar cell interconnect structure. In one embodiment, the module structure described herein includes a patterned adhesive layer that is disposed on a backsheet to receive and bond a plurality of patterned conducting ribbons thereon. The bonded conducting ribbons are then used to interconnect an array of solar cell devices to form a solar cell module that can be electrically connected to external components that can receive the solar cell module's generated electricity.

### CROSS-REFERENCE TO RELATED APPLICATIONS

This application is a continuation of co-pending U.S. patent application Ser. No. 12/842,022, filed Jul. 22, 2010, which claims benefit of U.S. Provisional Patent application Ser. No. 61/227,487, filed Jul. 22, 2009, which is herein incorporated by reference.

### BACKGROUND OF THE INVENTION

1. Field of the Invention

The present invention relates to photovoltaic modules fabricated using a monolithic module assembly.

2. Description of the Related Art

Solar cells are photovoltaic devices that convert sunlight directly into electrical power. Each solar cell generates a specific amount of electric power and are typically tiled into an array of interconnected solar cells, or modules, that are sized to deliver a desired amount of generated electrical power. The most common solar cell material is silicon, which is in the form of single or multicrystalline substrates, sometimes referred to as wafers. Because the amortized cost of forming silicon-based solar cells to generate electricity is higher than the cost of generating electricity using traditional methods, there has been an effort to reduce the cost to form solar cells.

One type of solar cell is a back-contact solar cell, or all back contact solar cell device. Back-contact solar cells have both the negative-polarity and positive-polarity contacts on the back surface of the formed solar cell device. Location of both polarity contacts on the same surface simplifies the electrical interconnection of the solar cells, and also opens the possibility of new assembly approaches and new module designs. “Monolithic module assembly” refers to assembly of the solar cell electrical circuit and the photovoltaic laminate in the same step and has been previously described (see, U.S. Pat. Nos. 5,951,786 and 5,972,732, and J. M. Gee, S. E. Garrett, and W P. Morgan, Simplified module assembly using back-contact crystalline-silicon silicon cells, 26^{th} IEEE Photovoltaic Specialists Conference, Anaheim, Calif., 29 Sep.-3 Oct. 1997). Monolithic module assembly starts with a backsheet typically patterned with an electrical conductor layer. Production of such patterned conductor layers on flexible large-area substrates is well known from printed-circuit board and flexible-circuit industries. The back-contact cells are placed on this backsheet with a pick-and-place tool. Such tools are well known and are very accurate with high throughput. The solar cells make electrical connection to the patterned electrical conductors on the back sheet during the lamination step, thereby making the laminated package and electrical circuit in a single step and with simple automation. The backsheet comprises materials such as solders or conductive adhesives that form the electrical connection during the lamination temperature-pressure cycle. The backsheet may optionally comprise, an electrical insulator layer to prevent shorting of the electrical conductors on the backsheet with the conductors on the solar cell. A polymer layer can also be provided between the backsheet and the solar cell for the encapsulation. This layer would provide low-stress adhesion of the backsheet to the solar cell. The polymer encapsulation layer could either be integrated with the backsheet, or could be inserted between the backsheet and the cells during the assembly process.

The typical fabrication sequence includes the formation of the solar cell circuit, assembly of the layered structure (glass, polymer, solar cell circuit, polymer, backsheet), and then lamination of the layered structure. The final steps include installation of the module frame and junction box, and testing of module. The solar cell circuit is typically made with automated tools (“stringer/tabbers”) that connect the solar cells in electrical series with copper (Cu) flat ribbon wires (“interconnects”). Several strings of series-connected solar cells are then electrically connected with wide Cu ribbons (“busses”) to complete the circuit. These busses also bring the current to the junction box from several points in the circuit for the bypass diodes and for connection to the cables.

This conventional photovoltaic module design and assembly approach is well known in the industry, and have the following disadvantages. First, the process of electrically connecting solar cells in series is difficult to automate so that stringer/tabbers have limited throughput and are expensive. Second, the assembled solar cell circuit formed between the array of solar cells is very fragile prior to the lamination step. Third, the copper (Cu) ribbon interconnect is highly stressed, so the conductivity of the copper interconnect is limited and the electrical losses due to the interconnect are large. Fourth, the use of interconnected and stressed copper ribbons is difficult to use in conjunction with thin crystalline-silicon solar cells, which as the industry advances continue to get thinner to reduce the solar cell cost. Fifth, the spacing between solar cells must be large enough to accommodate stress relief for the Cu interconnect wire, which reduces the module efficiency due to the non-utilized space between solar cells. This is particularly true when using silicon solar cells with positive and negative polarity contacts on opposite surfaces. Finally, this process of forming a solar cell using these methods has many steps resulting in a high manufacturing cost.

Various approaches enable fabricating active regions of the solar cell and the current carrying metal lines, or conductors, of the solar cells. However, there are several issues with these prior manufacturing methods. For example, the formation processes are complicated multistep labor intensive processes that add to costs required to complete the solar cells.

Therefore, there exists a need for improved methods and apparatus to form an interconnection between the active and current carrying regions formed on an array of interconnected solar cells.

### SUMMARY OF THE INVENTION

The present invention generally provides a solar cell module, comprising a backsheet having a mounting surface, a patterned adhesive layer comprising a plurality of adhesive regions that are disposed on the mounting surface, a plurality of patterned conductive ribbons that are disposed over the formed adhesive regions, a patterned interlayer dielectric material disposed over the patterned conductive ribbon and mounting surface, and a plurality of solar cells that are disposed over the patterned conductive ribbons to form an interconnected solar cell array, wherein each of the plurality of solar cells is electrically connected to a portion of a patterned conductive ribbon by use of a conductive material.

Embodiments of the present invention may also provide a method of forming a solar cell device, comprising depositing a patterned adhesive layer on a mounting surface of a backsheet, wherein the patterned adhesive layer forms a plurality of adhesive regions on the mounting surface, disposing a patterned conductive ribbon over each of the formed adhesive regions, depositing a patterned interlayer dielectric layer over the patterned conductive ribbons and the mounting surface, wherein the patterned interlayer dielectric layer has one or more vias formed over each of the patterned conductive ribbons, depositing a conductive material in the formed vias, and disposing a plurality of solar cells over the conductive material disposed in the vias to form an interconnected solar cell array.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIG. 1A is a bottom view illustrating a solar cell module according to one embodiment of the invention.

FIG. 1B is a bottom view illustrating a solar cell module according to one embodiment of the invention.

FIGS. 2A-2F are schematic cross-sectional views that illustrate the various processing steps used to form a solar cell module according to one embodiment of the invention.

FIG. 3 illustrates a processing steps used to form the solar cell module illustrated in FIGS. 2A-2F according to an embodiment of the invention.

For clarity, identical reference numerals have been used, where applicable, to designate identical elements that are common between figures. It is contemplated that features of one embodiment may be incorporated in other embodiments without further recitation.

### DETAILED DESCRIPTION

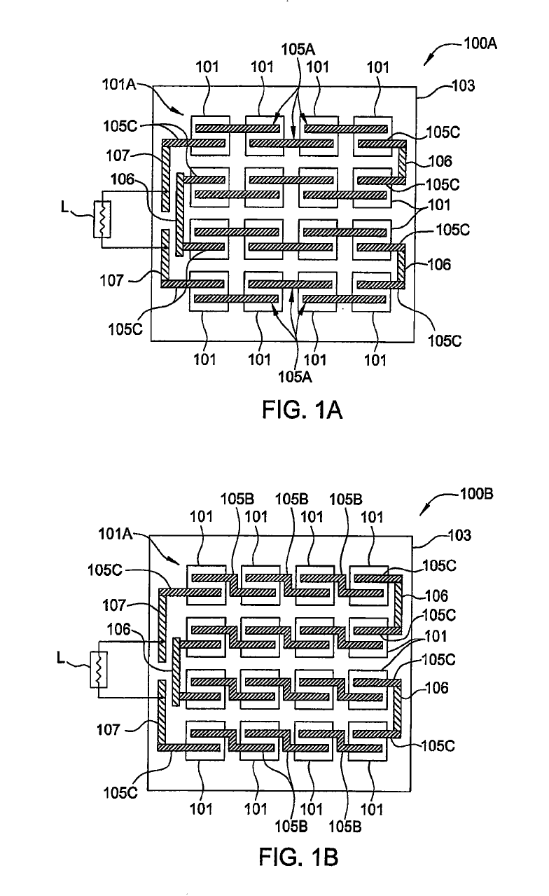

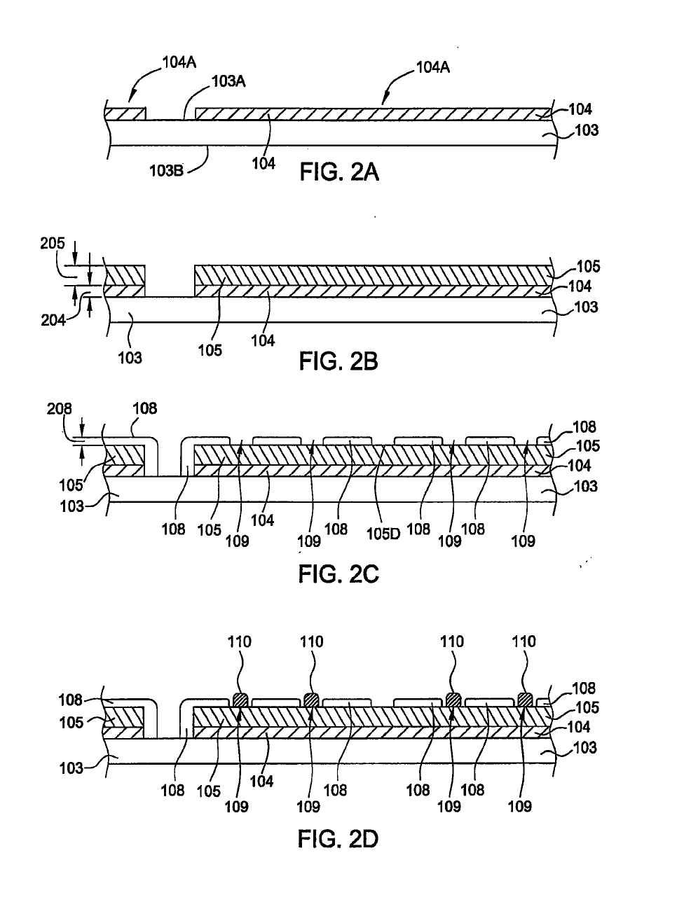

Embodiments of the invention contemplate the formation of a solar cell module comprising an array of interconnected solar cells that are formed using an automated processing sequence that is used to form a novel solar cell interconnect structure. In one embodiment, the module structure described herein includes a patterned adhesive layer that is disposed on a backsheet to receive and bond a plurality of patterned conducting ribbons thereon. The bonded conducting ribbons are then used to interconnect an array of solar cell devices to form a solar cell module that can be electrically connected to external components that can receive the solar cell module's generated electricity. Typical external components, or external loads “L” (FIG. 1A-1B), may include an electrical power grid, satellites, electronic devices or other similar power requiring units. Solar cell structures that are particularly benefited from the invention include back-contact solar cells, such as those in which both positive and negative contacts are formed only on the rear surface of the device. Solar cell devices that may benefit from the ideas disclosed herein may include devices containing materials, such as single crystal silicon, multi-crystalline silicon, polycrystalline silicon, germanium (Ge), gallium arsenide (GaAs), cadmium telluride (CdTe), cadmium sulfide (CdS), copper indium gallium selenide (CIGS), copper indium selenide (CuInSe₂), gallilium indium phosphide (GaInP₂), as well as heterojunction cells, such as GaInP/GaAs/Ge, ZnSe/GaAs/Ge or other similar substrate materials that can be used to convert sunlight to electrical power.

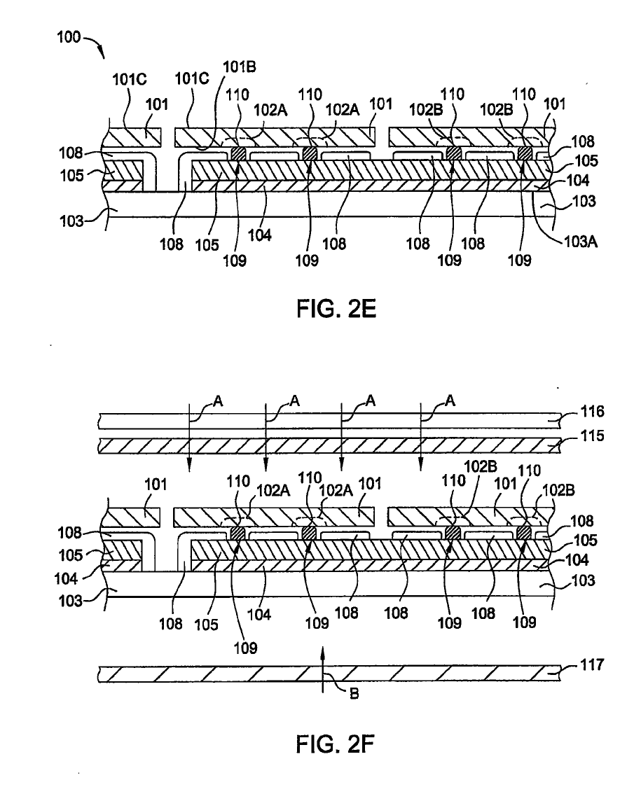

FIG. 1A is a bottom view of one embodiment of a solar cell module 100A having an array of interconnected solar cells 101 disposed over a top surface 103A (FIG. 2E) of a backsheet 103, as viewed through the bottom surface 103B (FIG. 2A) of the backsheet 103. In one embodiment, the solar cells 101 in the solar cell module 100A are back-contact type solar cells in which light received on a front surface 101 C (FIG. 2E) of a solar cell 101 is converted into electrical energy. In general, the solar cells 101 in the solar cell array 101A are connected in a desired way by use of conducting ribbons, such as reference numerals 105A and 105C in FIGS. 1A, or reference numeral 105 in FIGS. 2B-2F. In one example, the solar cells 101 in the solar cell array 101A are connected in series, such that the generated voltage of all the connected solar cells will add and the generated current remains relatively constant. In this configuration, the n-type and p-type regions formed in each interconnected solar cell are separately connected to regions formed in adjacent solar cells that have an opposing dopant type by use of the conductive ribbons 105A. One skilled in the art will appreciate that at the start and end of each row of the solar cell array 101A, conducting ribbons 105C and interconnects 106 can be used to join adjacent rows, and the interconnects 107 and conducting ribbons 105C, which are connected to solar cells 101 found at the start and end of the interconnected solar cell array 101A, can be used to connect the output of the solar cell array 101A to an external load “L”. In this configuration, for similarly configured solar cells 101, every other solar cell is rotated 180° relative to the surface of the backsheet 103, so that the n-type and p-type regions in adjacent cells will be aligned for easy connection using straight conducting ribbons 105A. One skilled in the art will appreciate that in some embodiments, the solar cells 101 can also be connected in parallel versus in series to limit the generated voltage, or increase the output current of the module.

FIG. 1B is a bottom view of one embodiment of a solar cell module 100B having an array of interconnected solar cells 101 disposed over a top surface 103A (FIG. 2E) of a backsheet 103, as viewed through the bottom surface 103B (FIG. 2A) of the backsheet 103. In one embodiment, the solar cells 101 in the solar cell module 100B are back-contact type solar cells. As discussed above, the solar cell array 101B may be connected in a desired way by use of conducting ribbons, such as reference numerals 105B and 105C in FIG. 1B, or reference numeral 105 in FIGS. 2B-2F. In one embodiment, solar cells 101 in a solar cell array 101A are connected in series in such a way that the formed n-type and p-type regions formed in each interconnected solar cell are separately connected to regions formed in adjacent solar cells that have an opposing dopant type by use of patterned conductive ribbons 105B. One skilled in the art will appreciate that at the start and end of each row of the solar cell array 101A, conducting ribbons 105C and interconnects 106 can be used to join adjacent rows, and the interconnects 107 and conducting ribbons 105C, which are connected to solar cells 101 found at the start and end of the interconnected solar cell array 101A, can be used to connect the output of the solar cell array 101A to an external load “L”. In this example, for similarly configured solar cells, each solar cell 101 is similarly oriented relative to the surface of the backsheet 103 so that the n-type and p-type regions in adjacent cells can be connected by use of a patterned conductive ribbon 105B. In this configuration, the patterned conductive ribbons 105B are shaped to connect the desired regions in adjacently positioned solar cells. In one embodiment, as shown in FIG. 1B, the patterned conducting ribbons are s-shaped to allow for a simplified positioning, orientation and interconnection of the solar cells 101 in the solar cell module 100B. As noted above, in some configurations it may be desirable to connect at least some of the solar cells 101 in the solar cell module 100B in parallel versus in series.

### Solar Cell Module Formation Processes

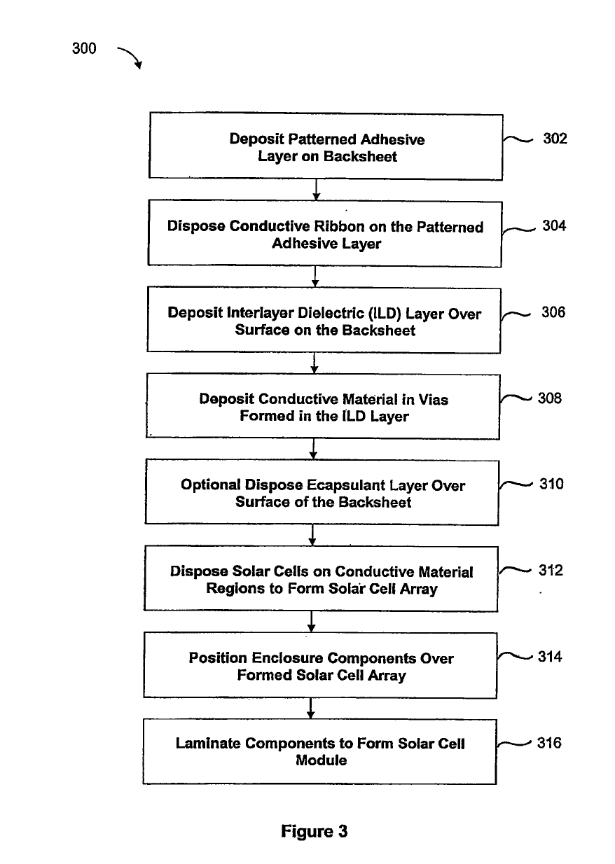

FIGS. 2A-2F are schematic cross-sectional views illustrating different stages of a processing sequence that are used to form a solar cell module 100. FIG. 3 illustrates a process sequence 300 used to form a solar cell module 100, similar to either of the solar cell modules 100A, 100B shown in FIGS. 1A and 1B. The sequence found in FIG. 3 corresponds to the stages depicted in FIGS. 2A-2F, which are discussed herein.

At box 302, and as shown in FIG. 2A, an adhesive material 104 is deposited in a desired pattern on the top surface 103A of a backsheet 103. In one embodiment, the deposited adhesive material 104 is deposited on the top surface 103A in a pattern to form a plurality of discrete adhesive regions 104A. In one embodiment, the adhesive material disposed in the adhesive regions 104A are deposited in shape(s) that will be substantially .covered by the conducting ribbons 105, which are placed thereon in a subsequent processing step. Since the patterned adhesive material 104 is covered by the conducting ribbons 105, the chance that the adhesive material will interact with the other solar cell module components (e.g., ILD layer 108, solar cells 101) during the subsequent processing steps is reduced. The reduced interaction between the adhesive material and the other solar cell module components prevents any out-gassing of the adhesive material, or the adhesive properties of the adhesive material itself, from contaminating or attacking one or more of the components in the formed solar cell module and/or or affecting the solar cell module manufacturing processes and device yield.

In one embodiment, the adhesive material 104 is a low temperature curable adhesive (e.g., <180° C.) that doesn't significantly out-gas. In one embodiment, the adhesive material 104 is a pressure sensitive adhesive (PSA) that is applied to desired locations on the top surface 103A of the backsheet 103. The adhesive material 104 can be applied to the backsheet 103 using screen printing, stenciling, ink jet printing, rubber stamping or other useful application methods that provides for accurate placement of the adhesive material in the desired locations on the backsheet 103. In one embodiment, the adhesive material 104 is a UV curable pressure sensitive adhesive (PSA) material that can be at least partially cured by the application of UV light during step 302. In some embodiments, the printing and curing of the adhesive material 104 can be done on a backsheet that is formed to allow for a continuous roll-to-roll process. In other embodiments, the adhesive material 104 could also be applied to backsheets 103 that have been cut to a desirable size prior to the application of the adhesive material 104.

In one embodiment, the backsheet 103 comprises a 100-200 μm thick polymeric material, such as polyethylene terephthalate (PET), polyvinyl fluoride (PVF), kapton or polyethylene. In one example, the backsheet 103 is a 125-175 μm thick sheet of polyethylene terephthalate (PET). In another embodiment, the backsheet 103 comprises one or more layers of material that may include polymeric materials and metals (e.g., aluminum). In one example, the backsheet 103 comprises a 150 μm polyethylene terephthalate (PET) sheet, a 25 μm thick sheet of polyvinyl fluoride that is purchased under the trade name DuPont 2111 Tedlar™, and a thin aluminum layer. It should be noted that the lower surface 103B of the backsheet 103 will generally face the environment, and thus portions of the backsheet 103 may be configured to act as a UV or vapor barrier. Thus, the backsheet 103 is generally selected for its excellent mechanical properties and ability to maintain its properties under long term exposure to UV radiation. A PET layer may be selected because of its excellent long term mechanical stability and electrical isolative properties. The backsheet, as a whole, is preferably certified to meet the IEC and UL requirements for use in a photovoltaic module.

Next, at step 304, and as shown in FIG. 2B, the conducting ribbons 105 are cut to a desired shape and/or length, and placed on the patterned adhesive material 104. The process of placing the conducting ribbons 105 on the adhesive material, may include applying pressure to the conducting ribbons 105 to assure that they are sufficiently affixed to the backsheet 103. In one embodiment, the conducting ribbons 105 comprise a thin soft annealed copper material that has a thickness 205 (FIG. 2B) that is between about 25 and 250 μm thick, such as about 125 μm thick. In one embodiment, conducting ribbons 105 are a copper material that is coated with a layer of tin (Sn) to promote the electrical contact between the conducting ribbons 105 and conductive material 110, which is described below. In another embodiment, the conducting ribbons 105 comprise an aluminum material that is coated with a layer of nickel (Ni). In one example, the conducting ribbons 105 are typically 6.0 mm wide, though other widths could easily be used. The conducting ribbons 105 are typically cut to a desired shape and length from a continuous roll of ribbon material, and can be placed on the backsheet 103 using a pick and place robot or other similar device.

Next, at step 306, and as shown in FIG. 2C, an interlayer dielectric (ILD) material 108 is disposed over the top surface 103A of the backsheet 103 and conducting ribbons 105. In one embodiment, the interlayer dielectric (ILD) material 108 is a patterned layer, or discontinuous layer, that has a plurality of vias 109, or holes, formed over a surface 105D (FIG. 2C) of the conducting ribbons 105. The patterned interlayer dielectric (ILD) material 108 can be applied to the backsheet 103 and conducting ribbons 105 using a screen printing, stenciling, ink jet printing, rubber stamping or other useful application method that provides for accurate placement interlayer dielectric (ILD) material 108 on these desired locations. In one embodiment, the interlayer dielectric (ILD) material 108 is a UV curable material that can be reliably processed at low temperatures, such as an acrylic or phenolic material. In one embodiment, the interlayer dielectric (ILD) material 108 is deposited to form a layer that is between about 18 and 25 μm thick over the conducting ribbons 105. In this configuration, the thickness of the ILD material 108 is controlled to minimize the path length through which the generated current must pass, as it flows through the conductive material 110 (FIG. 2D) that is disposed between the conducting ribbon 105 and solar cells 101.

Next, at step 308, and as shown in FIG. 2D, the conductive material 110 is disposed within the vias 109 formed in the interlayer dielectric (ILD) material 108. The conductive material 110 can be positioned in the vias 109 using a screen printing, ink jet printing, ball application, syringe dispense or other useful application method that provides for accurate placement of the conductive material 110 in these desired locations. In one embodiment, the conductive material 110 is a screen printable electrically conductive adhesive (ECA) material, such as a metal filled epoxy, metal filled silicone or other similar material that has a conductivity that is high enough to conduct the electricity generated by the formed solar cell 101. In one example, the conductive material 110 has a resistivity that is about 1×10⁻⁵ Ohm-centimeters or less.

In an alternate embodiment of step 308, the conductive material 110 is dispensed on the cell bond pads found on the back surface 101B of the solar cells 101, so that these deposited regions can then be mated with the vias 109 formed in the ILD material 108 in a later step.

Next, at step 310, and as shown in FIG. 2D, a module encapsulant material (not shown) is optionally disposed over the backsheet 103, interlayer dielectric (ILD) material 108 and conducting ribbons 105 to prevent environmental encroachment into the region formed between the backsheet 103 and solar cells 101. The module encapsulant material is a polymeric sheet that will liquefy during the subsequent lamination process and help bond the cells to the backsheet. The module encapsulant material may comprise ethylene vinylacetate (EVA) or other suitable encapsulation material. The material is preferably of sufficient thickness to fill around the conducting ribbons 105 and provide a mechanical barrier between the PV cells and the conducting ribbons 105. The module encapsulant sheet is preferably cut to a size such that it extends past the edges of the backsheet. In one embodiment, prior to placement over the backsheet 103, holes are punched in the module encapsulant material to allow the conductive material 110 to extend between the solar cells 101 and conductive ribbons 105. The diameter of the holes is determined by the amount of area needed for the interconnect formed between the conductive ribbons 105 and the conductive material 110. The process of punching or removal of the module encapsulant material to form the holes can be performed in several ways, such as a mechanical punching processes or a laser ablation processes. Once the module encapsulant is punched it is laid up on the backsheet 103 over the conductive ribbons 105 and registered, such that the holes in the module encapsulant line up with the vias 109 formed on the conductive ribbons 105.

Next, at step 312, as shown in FIG. 2E, the solar cells 101 are place over the conducting ribbons 105 so that the conductive material 110 is aligned with the solar cell bond pads that are coupled to the active regions 102A or 102B formed in the solar cell 101. In one embodiment, the active region 102A is an n-type region in a first solar cell, and the active region 102B is a p-type region formed in a second solar cell.

Next, at step 314, as shown in FIG. 2E, one or more enclosure components are positioned over the solar cell module 100, so that the whole structure can be encapsulated during a subsequent lamination process. In one embodiment, the enclosure components include a sheet of front encapsulant 115, a cover glass 116 and an optional outer-backsheet 117. The front encapsulate 115 may be similar to the module encapsulant described above, and may comprise ethylene vinylacetate (EVA) or other suitable thermoplastic material. The optional outer-backsheet 117 may comprise a sheet of polyvinyl fluoride (e.g., DuPont 2111 Tedlar™) and a thin aluminum layer, that act as a vapor and UV barrier. The aluminum layer in the outer-backsheet 117, serves primarily as a vapor barrier, is typically 35 to 50 μm thick, although a thinner barrier can be used to provide better flexibility while maintain good environmental isolation. It is also possible to use a non metallic film with properties that provide for a water vapor transmission rate (WTVR) below 1×10⁻⁴ g/m²/day.

Next, at step 316, once the stack-up of the enclosure components is complete, the complete assembly is placed in a press laminator. The lamination process causes the encapsulant to soften, flow and bond to all surfaces with in the package, and the adhesive layer 104 and conductive material 110 to cure in a single processing step. During the lamination process the conductive material 110 is able to cure and form electrical bonds between the connection regions of the solar cells 101 and conductive ribbons 105. The lamination step applies pressure and temperature to the complete assembly, such as the glass 116, encapsulant 115, solar cells 101, conductive material 110, conductive ribbon 105, adhesive material 104 and backsheet 103, while a vacuum pressure is maintained around the complete assembly. After the lamination step, a frame is placed around the encapsulated the solar cell module for ease of handling, mechanical strength, and for locations to mount the photovoltaic module. A “junction box”, where electrical connection to other components of the complete photovoltaic system (“cables”) is made, may also be added to the laminated complete assembly.

The advantage of this construction method is that it uses commercially available materials and processes while avoiding the problems associated with conventional PV module assembly processes. The cells are planar with no ribbon passing between the top and bottom surfaces of the cell. This allows the cells to be placed closer together while avoiding stressing the edges where ribbon passes from the top to the bottom of the cell. The planar construction also provides for lower mechanical stresses during thermal cycling, which the module will undergo on a daily basis when installed in the field.

Although the invention has been described in detail with particular reference to these preferred embodiments, other embodiments can achieve the same results. Variations and modifications of the present invention will be obvious to those skilled in the art and it is intended to cover all such modifications and equivalents. The entire disclosures of all patents, references, and publications cited above are hereby incorporated by reference. The advantages of solar cell module described herein include the following. First, a single thermal processing step, or lamination step, is used to encapsulate the solar cell module to reduce the number of processing steps and reduce the solar cell manufacturing cost. Second, the planar geometry of the formed solar cell module is easier to automate, which reduces the cost, and improves the throughput of the production tools, while also introducing less stress in the formed device and enabling the use of thin Si solar cells. Third, a smaller spacing between solar cells may be used compared to conventional photovoltaic modules with copper ribbon interconnects, which increases the module efficiency and reduces the solar cell module cost. In some configurations, the copper busses at the end of the modules can also be reduced or eliminated, which also reduces module size for reduced cost and improved efficiency. Fourth, the number and location of the contact points formed on a solar cell can be easily optimized since the geometry is only limited by the patterning technology. This is unlike stringer/tabbers designs where additional copper interconnect straps or contacting points increase cost. The net result is that the cell and interconnect geometry can be more easily optimized with monolithic module assembly. Fifth, the electrical circuit on the backsheet can cover nearly the entire surface. The conductivity of the electrical interconnects can be made higher because the effective interconnect is much wider. Meanwhile, the wider conductor can be made thinner (typically less than 50 μm) and still have low resistance. A thinner conductor is more flexible and reduces stress. Finally, the spacing between solar cells can be made small since no provision for stress relief of thick copper interconnects is needed. This improves the module efficiency and reduces the module material cost (less glass, polymer, and backsheet due to reduced area).

While the foregoing is directed to embodiments of the present invention, other and further embodiments of the invention may be devised without departing from the basic scope thereof, and the scope thereof is determined by the claims that follow.

1. A substrate for interconnecting photovoltaic devices, comprising:
a backsheet comprising a first polymeric layer that has a mounting surface;
a patterned adhesive layer comprising a plurality of adhesive regions that are disposed on the mounting surface; and
a plurality of patterned conductive ribbons that are disposed over the formed adhesive regions.

2. The substrate of claim 1, wherein the plurality of patterned conductive ribbons comprise aluminum.

3. The substrate of claim 1, wherein the plurality of patterned conductive ribbons comprise a layer of tin disposed over a copper containing material, or a layer of nickel disposed over an aluminum containing material.

4. The substrate of claim 1, further comprising a patterned interlayer dielectric material disposed over the plurality of patterned conductive ribbons and mounting surface.

5. The substrate of claim 4, further comprising an encapsulant layer disposed over the patterned interlayer dielectric material, wherein openings formed in the encapsulant layer and the patterned interlayer dielectric material are aligned so that each of the openings expose a portion of each of the plurality of patterned conductive ribbons.

6. The substrate of claim 1, wherein the first polymeric layer comprises a material selected from a group consisting of polyethylene terephthalate (PET), polyvinyl fluoride (PVF) and polyethylene.

7. The substrate of claim 1, wherein the patterned adhesive layer is covered by the plurality of patterned conductive ribbons, and comprise a pressure sensitive adhesive.

8. The substrate of claim 1, wherein the plurality of patterned conductive ribbons has a non-linear shape.

9. The substrate of claim 1, wherein the plurality of patterned conductive ribbons comprise a layer of tin disposed over a copper containing material, or a layer of nickel disposed over an aluminum containing material.

10. A substrate for interconnecting photovoltaic devices, comprising:
a backsheet comprising a first metal layer that is bonded to a bonding surface of a first polymeric layer, wherein the first polymeric layer has a mounting surface;
a patterned adhesive layer comprising a plurality of adhesive regions that are disposed on the mounting surface;
a plurality of patterned conductive ribbons that are disposed over the formed adhesive regions, wherein the plurality of patterned conductive ribbons have a non-linear shape, and form part of a circuit used to interconnect two or more back contact solar cells; and
a patterned interlayer dielectric material disposed over the patterned conductive ribbons and mounting surface.

11. The substrate of claim 10, further comprising an encapsulant layer disposed over the patterned interlayer dielectric material, wherein openings formed in the encapsulant layer and the patterned interlayer dielectric material are aligned so that each of the openings expose a portion of each of the plurality of patterned conductive ribbons.

12. The substrate of claim 10, wherein the first polymeric layer comprises a material selected from a group consisting of polyethylene terephthalate (PET), polyvinyl fluoride (PVF) and polyethylene.

13. The substrate of claim 10, wherein the formed adhesive regions are covered by the plurality of patterned conductive ribbons, and the formed adhesive regions comprises a pressure sensitive adhesive.

14. The substrate of claim 10, wherein the plurality of patterned conductive ribbons are planar in shape.

15. The substrate of claim 10, wherein the plurality of patterned conductive ribbons comprise a layer of tin disposed over a copper containing material, or a layer of nickel disposed over an aluminum containing material.

16. A substrate for interconnecting photovoltaic devices, comprising:
a backsheet comprising a first metal layer that is bonded to a bonding surface of a first polymeric layer, wherein the first polymeric layer has a mounting surface;
a patterned adhesive layer comprising a plurality of adhesive regions that are disposed on the mounting surface;
a plurality of patterned conductive ribbons that are disposed over the formed adhesive regions, wherein the plurality of patterned conductive ribbons comprise aluminum and form part of a circuit used to interconnect two or more back contact solar cells; and
a patterned interlayer dielectric material disposed over the patterned conductive ribbons and mounting surface, and having a plurality of holes formed there through.

17. The substrate of claim 16, further comprising an encapsulant layer disposed over the patterned interlayer dielectric material, wherein openings formed in the encapsulant layer and the holes formed in the patterned interlayer dielectric material are aligned to expose a portion of each of the plurality of patterned conductive ribbons.

18. The substrate of claim 16, wherein the first polymeric layer comprises a material selected from a group consisting of polyethylene terephthalate (PET), polyvinyl fluoride (PVF) and polyethylene.

19. The substrate of claim 16, wherein the plurality of patterned conductive ribbons are planar in shape and

20. The substrate of claim 19, wherein the plurality of patterned conductive ribbons cover the formed adhesive regions.
